(19) United States
(12) Patent Application Publication
(10) Pub. No.: US 2026/0147392 A1
(43) Pub. Date: May 28, 2026

(54) SYSTEMS AND METHODS USING TELEMETRY DATA TO EVALUATE A HEAT SPREADER

(71) Applicant: Dell Products L.P., Round Rock, TX (US)

(72) Inventors: Ting-Chiang Huang, New Taipei City (TW); Kang-Wei Fan, Taoyuan City (TW)

(73) Assignee: Dell Products L.P., Round Rock, TX (US)

(21) Appl. No.: 18/956,152

(22) Filed: Nov. 22, 2024

(51) Int. Cl. G06F 1/20; H05K 7/20

(52) U.S. Cl. CPC G06F 1/206; H05K 7/20509

(57) ABSTRACT

A computer system may include program code, which when executed by at least one processor of the computer system, cause the computer system to evaluate a presence or an operability of a heat spreader. The computer system may be configured to generate data points over time, where each data point may represent a measurement from a first thermal sensor and a measurement from a second thermal sensor. As more data points are generated, the computer system may be configured to determine a slope associated with a linear function of the data points. The computer system may further compare the slope with a reference slope to determine the presence or operability of the heat spreader.

### FIELD

This disclosure relates generally to Information Handling Systems (IHSs), and more specifically, to systems and methods for evaluating a heat spreader based on telemetry data.

### BACKGROUND

As the value and use of information continues to increase, individuals and businesses seek additional ways to process and store it. One option available to users is an Information Handling System (IHS). An IHS generally processes, compiles, stores, and/or communicates information or data for business, personal, or other purposes thereby allowing users to take advantage of the value of the information. Because technology and information handling needs and requirements vary between different users or applications, IHSs may also vary regarding what information is handled, how the information is handled, how much information is processed, stored, or communicated, and how quickly and efficiently the information may be processed, stored, or communicated.

Variations in IHSs allow for IHSs to be general or configured for a specific user or specific use such as financial transaction processing, airline reservations, enterprise data storage, or global communications. In addition, IHSs may include a variety of hardware and software components that may be configured to process, store, and communicate information and may include one or more computer systems, data storage systems, and networking systems.

### SUMMARY

According to an embodiment, a method includes: accessing first temperature information for a first thermal sensor disposed on a storage drive of an information handling system (IHS); accessing second temperature information for a second thermal sensor disposed on a circuit board, wherein the storage drive is arranged above the circuit board; generating a plurality of data points over time, wherein each of the data points represents a first dimension associated with the first temperature information and a second dimension associated with the second temperature information; determining a linear function based on the plurality of data points; and determining whether a heat spreader is disposed between the first thermal sensor and the second thermal sensor based on the linear function

According to an embodiment, Information Handling System (IHS), includes: a processor; and a memory coupled to the processor, the memory having program instructions stored thereon that, upon execution by the processor, cause the IHS to: a processor; and a memory coupled to the processor, the memory having program instructions stored thereon that, upon execution by the processor, cause the IHS to: access first temperature information for a first thermal sensor disposed on a first layer in an information handling system (IHS); access second temperature information for a second thermal sensor disposed on a second layer in the IHS; generate a plurality of data points over time, wherein each of the data points represents a first dimension associated with the first temperature information and a second dimension associated with the second temperature information; determine a linear function based on the plurality of data points; and evaluate a presence of a heat spreader between the first thermal sensor and the second thermal sensor or an effectiveness of the heat spreader based on the linear function.

According to an embodiment, a hardware memory device has program instructions stored thereon that, upon execution by a processor of an IHS, causes the IHS to: receive first telemetry data and second telemetry data from a first sensor and a second sensor, respectively, of the IHS; generate a plurality of data points over time, wherein each of the data points represents the first telemetry data and the second telemetry data; determine a linear function based on the plurality of data points; evaluate a slope of the linear function; and determine that a heat spreader is either not present in the IHS or is not operable in the IHS based on evaluating the slope of the linear function.

### BRIEF DESCRIPTION OF THE DRAWINGS

The present invention(s) is/are illustrated by way of example and is/are not limited by the accompanying figures, in which like references indicate similar elements. Elements in the figures are illustrated for simplicity and clarity and have not necessarily been drawn to scale.

FIG. 1 is a block diagram of components of an example Information Handling System (IHS), according to some embodiments.

FIG. 2 is an illustration of an example SSD assembly, according to some embodiments.

FIG. 3 is an illustration of a graph of example curves of thermal performance, according to various embodiments.

FIG. 4 is an illustration of a graph of example curves of thermal performance, according to various embodiments.

FIG. 5 is an illustration of example graphs, showing example curves of thermal performance, according to various embodiments.

FIG. 6 is an illustration of an example method for addressing thermal performance of an IHS, according to various embodiments.

FIG. 7 illustrates an example arrangement of layers in an IHS, according to some embodiments.

FIG. 8 illustrates curves associated with operation of the arrangement of layers of FIG. 7, according to some embodiments.

### DETAILED DESCRIPTION

For purposes of this disclosure, an Information Handling System (IHS) may include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an IHS may be a personal computer (e.g., desktop or laptop), tablet computer, mobile device (e.g., Personal Digital Assistant (PDA) or smart phone), server (e.g., blade server or rack server), a network storage device, or any other suitable device and may vary in size, shape, performance, functionality, and price. An example of an IHS is described in more detail below. It should be appreciated that although certain embodiments are discussed in the context of a personal computing device, other embodiments may utilize various other types of IHSs.

A given IHS may have heat generating sources, such as processing cores, random access memory (RAM) modules, solid-state drives (SSDs), and the like. Such IHSs may further include thermal algorithms, which monitor the temperatures in the IHS using a multitude of different thermal sensors. The thermal algorithm may track the temperatures detected by the sensors over time in an attempt to prevent overheating of one or more components of the IHS. In an instance in which a heat generating source may be near a heat limit, a thermal algorithm may reduce a clock speed or a voltage used by the heat generating source, thereby reducing thermal generation but also reducing performance.

Various IHSs may further include hardware to manage thermal generation. An example includes a heat spreader, sometimes also referred to as a thermal pad. A heat spreader may include any appropriate material, such as a composite of silicone and metal, a copper plate, an aluminum plate, and/or the like. A heat spreader may sometimes include a relatively large surface area and be in contact with a heatsink. Examples of heatsinks may include metal finned heatsinks, thermally conductive circuit boards, and/or the like. The heat spreader is configured so that heat that is generated at a relatively small area of a heat generator may be spread out over the relatively large surface area of the heat spreader and allow for the heat to be transferred to a heatsink.

However, some IHSs may experience thermal issues caused by the absence of a heat spreader or the ineffectiveness of a heat spreader. In one example, an IHS may be manufactured so that it has an SSD, thermally adjacent a heat spreader, and the heat spreader may be thermally adjacent a printed circuit board for removal of the heat. However, a user of the IHS may make modifications, such as by changing out the SSD with another SSD, and that user may intentionally or unintentionally fail to install a heat spreader. The IHS may then be more prone to overheating events, leading to a reduction in performance by virtue of the thermal algorithm.

In another example, an IHS may be manufactured to include a heat spreader between a processor core and a heatsink. However, the heat spreader may prove to be ineffective or inoperable. For instance, a heat spreader may be installed incorrectly, leaving a gap between the heat spreader and the heat source and/or the heat spreader and a heatsink. As a result, the heat may not be sunk effectively, which may result in the thermal algorithm throttling the IHS and reducing performance.

Various embodiments provide techniques to determine whether a heat spreader is present and/or operable, thereby allowing for remediation if appropriate. In one example, an IHS may track telemetry data. One example telemetry data that may be tracked is temperature information from a first thermal sensor and temperature information from a second thermal sensor. For instance, the first thermal sensor may be placed in a first layer within the IHS, and the second thermal sensor may be placed in a different layer within the IHS. The difference in temperature between the two thermal sensors may be indicative of operability and/or presence of a heat spreader.

Continuing with the example, the IHS may track the telemetry data over time, producing multiple data points over time. The data points may be configured to be plotted on a multidimensional space, such as a two-dimensional space, with a first dimension corresponding to the first thermal sensor reading and the second dimension corresponding to the second thermal sensor reading. The IHS may be configured to perform a curve fitting, such as a linear curve fitting, on the data points. In such an instance, the slope of the line (where the line may be represented by a linear function) may be indicative of a rate of increase of the first thermal sensor reading versus the rate of increase of the second thermal sensor reading.

In some examples, the IHS may be configured with a database of reference slopes, where those reference slopes may be determined previously through testing and/or simulation and at different ambient temperatures. The IHS may be configured to select a reference slope based on current ambient temperature and then use the reference slope as a threshold, where the slope of the linear function being above the reference slope indicates an inoperable or absent heat spreader and the slope of the linear function being below the reference slope may indicate an operable or present heat spreader.

In an instance in which it is determined that the heat spreader is either inoperable or is absent, the IHS may provide a notification. Examples of notifications may include an indication on a graphical user interface (GUI) of the IHS or a different IHS, a message to a remote IHS, and/or the like. In response, a repair service may perform an on-site visit and replace or repair the heat spreader.

Various embodiments may include advantages over prior solutions. For instance, heat spreader absence or inoperability may be a relatively common cause of performance throttling in some IHS models. Furthermore, heat spreader absence or inoperability may be relatively difficult to diagnose without physically opening up the IHS itself and performing an inspection by a human technician. By contrast, various embodiments may allow for heat spreader absence or inoperability to be detected without physically opening up the IHS. In some use cases, a user of an IHS may contact a support center, run an algorithm configured to evaluate absence and/or operability of a heat spreader, and provide the results of the algorithm to the support center. The support center may then determine whether the cause of the support request may be due to an absent or inoperable heat spreader. Furthermore, should an on-site visit be appropriate, the support center may send a technician who is equipped to repair and/or replace the heat spreader of the IHS. In other words, various embodiments may increase efficiency by allowing for relatively accurate diagnosis of performance issues and for appropriate preparation by a technician for an on-site visit.

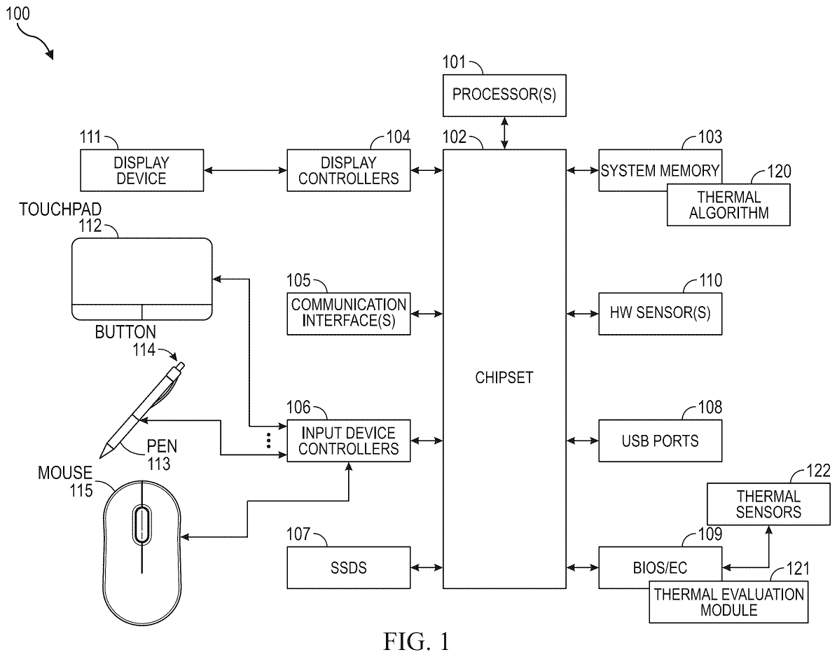

FIG. 1 is a block diagram of components of IHS 100, according to some embodiments. As depicted, IHS 100 includes processor 101. In various embodiments, IHS 100 may be a single-processor system, or a multi-processor system including two or more processor cores. Processor 101 may include any processor capable of executing program instructions, such as a PENTIUM series processor, or any general-purpose or embedded processors implementing any of a variety of Instruction Set Architectures (ISAs), such as an x86 ISA or a Reduced Instruction Set Computer (RISC) ISA (e.g., POWERPC, ARM, SPARC, MIPS, etc.).

IHS 100 includes chipset 102 coupled to processor 101. Chipset 102 may provide processor 101 with access to several resources. In some cases, chipset 102 may utilize a QuickPath Interconnect (QPI) bus to communicate with processor 101. Chipset 102 may also be coupled to communication interface(s) 105 to enable communications between IHS 100 and various wired and/or wireless networks, such as Ethernet, WiFi, BLUETOOTH, cellular or mobile networks (e.g., CDMA, TDMA, LTE, etc.), satellite networks, or the like. In some cases, communication interface(s) 105 may be coupled to chipset 102 via a PCIe bus.

Chipset 102 may be coupled to display controller(s) 104, which may include one or more or graphics processor(s) (GPUs) on a graphics bus, such as an Accelerated Graphics Port (AGP) or Peripheral Component Interconnect Express (PCIe) bus. As shown, display controller(s) 104 provide video or display signals to display device 111. In other implementations, any number of display controller or display devices may be used.

Display device 111 may include Liquid Crystal Display (LCD), Light Emitting Diode (LED), organic LED (OLED), or other thin film display technologies. Display device 111 may include a plurality of pixels arranged in a matrix, configured to display visual information, such as text, two-dimensional images, video, three-dimensional images, etc. In some cases, display device 111 may be provided as a single continuous display, rather than two discrete displays. In some embodiments, display device 111 may be utilized to provide interactive visual output, such as on a graphical user interface (GUI), for a human user.

Chipset 102 may provide processor 101 and/or display controller(s) 104 with access to system memory 103. In various embodiments, system memory 103 may be implemented using any suitable memory technology, such as static RAM (SRAM), dynamic RAM (DRAM) or magnetic disks, or any nonvolatile/Flash-type memory, such as a solid-state drive (SSD) or the like. Memory 103 may store program instructions that, upon execution by processor 101, perform functionality of an application.

In the example of FIG. 1, memory 103 includes program instructions that, when executed, provide functionality of a thermal algorithm 120. For instance, the thermal algorithm may receive information from thermal sensors 122 and adjust operating voltages and clock speeds as appropriate to prevent or ameliorate overheating situations. In some examples, thermal algorithm 120 may be implemented as an application that runs on top of an operating system, where the operating system is executed by the processors 101. In another example, thermal algorithm 120 may be implemented as part of the operating system, such as a part of the kernel, though the scope of embodiments may include any appropriate configuration for the thermal algorithm 120.

Chipset 102 may also provide access to one or more storage drives, such as solid-state drives (SSDs) 107. In certain embodiments, chipset 102 may also provide access to one or more hard disk drives, optical drives or other removable-media drives. In certain embodiments, chipset 102 may also provide access to one or more Universal Serial Bus (USB) ports 108.

Chipset 102 may further provide access to input device controllers 106, for example, a super I/O controller, firmware or software functionality, or the like. Examples of user input devices which may be communicatively coupled to input device controllers 106 include, but are not limited to, a keyboard, mouse 115, touchpad 112, stylus or pen 113 (with button or switch 114), totem, etc. Input device controllers 106 may represent multiple controllers, such that each of the user input devices may correspond to a respective controller (e.g., a touchpad may have its own touchpad controller). Each of the input devices may interface with its respective controller 106 through a wired or wireless connection (e.g., via communication interfaces(s) 105).

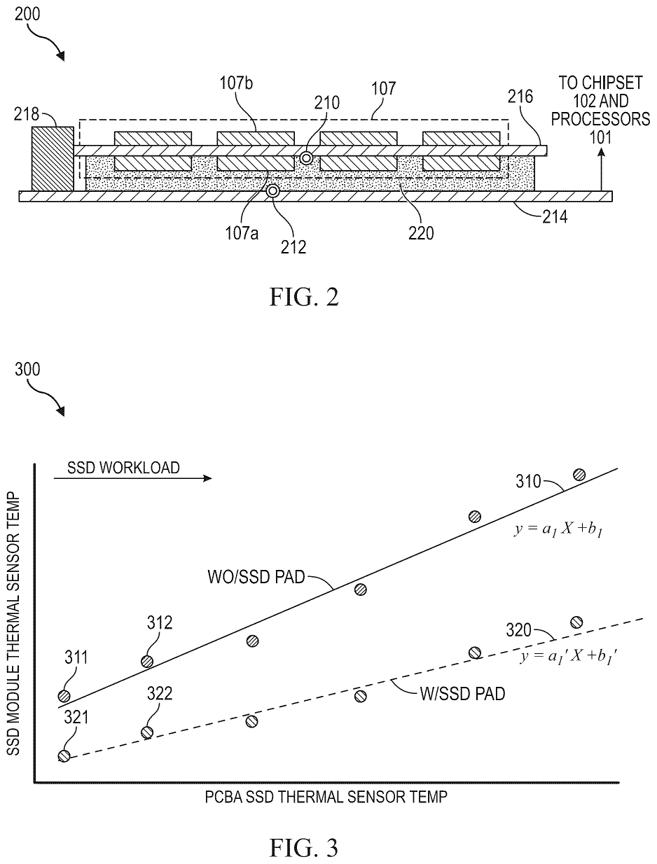

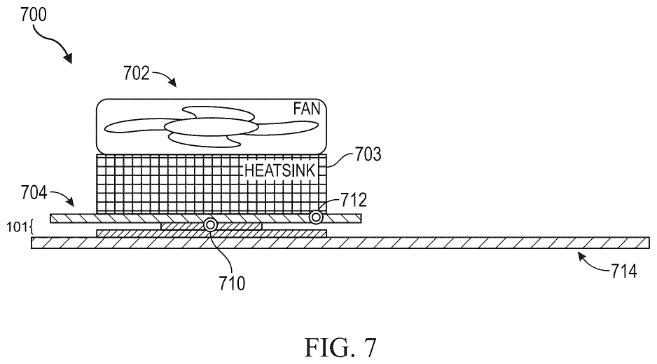

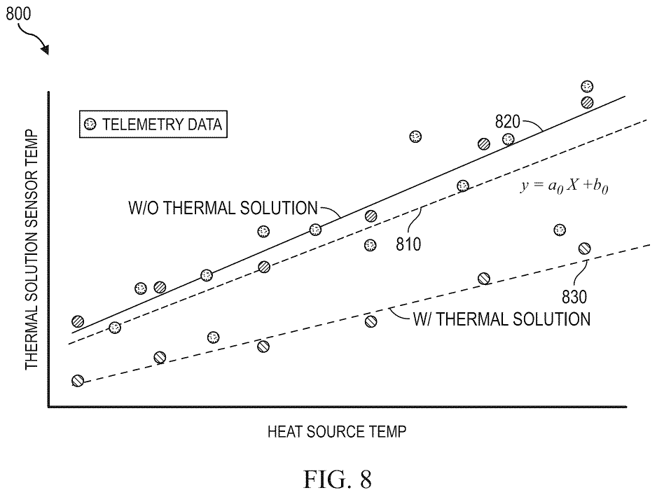

In certain embodiments, chipset 102 may also provide an interface for communications with one or more hardware sensors 110. Sensors 110 may be disposed on or within the chassis of IHS 100, and may include, but are not limited to: electric, magnetic, radio, optical, infrared, force, pressure, acoustic, ultrasonic, proximity, position, deformation, bending, direction, movement, velocity, rotation, and/or acceleration sensor(s). Example placement of thermal sensors is described in more detail with respect to FIGS. 2 and 7.

Upon booting of IHS 100, processor(s) 101 may utilize Basic Input/Output System (BIOS) instructions of BIOS/Embedded Controller (EC) 109 to initialize and test hardware components coupled to IHS 100 and to load an OS for use by IHS 100. The BIOS provides an abstraction layer that allows the OS to interface with certain hardware components that are utilized by IHS 100. Via the hardware abstraction layer provided by the BIOS, software stored in system memory 103 and executed by processor 101 can interface with certain I/O devices that are coupled to IHS 100. The Unified Extensible Firmware Interface (UEFI) was designed as a successor to BIOS. As a result, many modern IHSs utilize UEFI in addition to or instead of a BIOS. As used herein, BIOS is intended to also encompass UEFI.

EC 109 may be installed as a Trusted Execution Environment (TEE) component to the motherboard of IHS 100. EC 109 may implement operations for interfacing with a power adapter in managing power for IHS 100. Such operations may be utilized to determine the power status of IHS 100, such as whether IHS 100 is operating from battery power or is plugged into an AC power source. Firmware instructions utilized by EC 109 may be used to provide various core operations of IHS 100, such as power management and management of certain modes of IHS 100 (e.g., turbo modes, maximum operating clock frequencies of certain components, etc.).

In the example of FIG. 1, thermal evaluation module 121 may include computer program instructions, which are included in the firmware of the BIOS. The embedded controller 109 may read and execute those program instructions, thereby providing the functionality of the thermal evaluation module 121. In various embodiments, the thermal evaluation module 121 may be configured to receive thermal readings from various thermal sensors 122, generate data points over time using the readings from the thermal sensors 122, perform a linear curve fitting on the data points, analyze the curve, and determine operability and/or presence of a heat spreader of the IHS based on analyzing the curve. Thermal sensors 210, 210 (FIGS. 2) and 710, 712 (FIG. 7) are examples of thermal sensors that may be configured as shown with respect to thermal sensors 122. In this example, thermal sensors 122 are configured to interface with EC 109.

In other embodiments, IHS 100 may not include all the components shown in FIG. 1. In other embodiments, IHS 100 may include other components in addition to those that are shown in FIG. 1. Furthermore, some components that are represented as separate components in FIG. 1 may instead be integrated with other components. For example, all or a portion of the operations executed by the illustrated components may instead be provided by components integrated into processor(s) 101 as systems-on-a-chip. As such, in certain embodiments, IHS 100 may be implemented as different classes of computing devices including, but not limited to: servers, workstations, desktops, laptops, appliances, video game consoles, tablets, smartphones, etc.

FIG. 2 is an illustration of an example SSD assembly 200, according to some embodiments. For instance, the SSD assembly 200 includes SSD 107. SSD 107 includes a multitude (e.g., eight) of memory modules, exemplified by memory modules 107a and 107b, mounted on a first printed circuit board (PCB) 216. The memory modules of the SSD 107 may be communicatively coupled to metal layers (not shown) of PCB 216, and SSD connector 218 may provide electrical communication between the metal layers of PCB 216 and metal layers (not shown) of the motherboard 214. The motherboard 214 may be implemented as a PCB or other circuit board and may be communicatively coupled to the chipset 102 and the processors 101 via the metal layers of the motherboard 214.

The processors 101 may perform read and write operations to store data to the SSD 107 or to retrieve data from the SSD 107, including by communicating to the SSD 107 by the metal layers of motherboard 214 and PCB 216. Read operations and write operations made at the SSD 107 may be affected by an operating voltage of the SSD 107 and by an operating clock of the SSD 107. For instance, the SSD 107 may be configured to have a default operating voltage and a default clock speed, thereby allowing for a known level of performance, such as measured in input output operations per second. A decrease in either or both of the operating voltage and the operating clock speed may result in a decrease in performance. Similarly, an increase in either or both of the operating voltage and the operating clock speed may result in an increase in performance, where an increase in performance is typically associated with an increase in generated heat. As noted above, there may be a thermal algorithm 120, which measures thermal conditions and may decrease an operating voltage and/or a clock speed when appropriate to reduce an amount of heat generated by the SSD 107.

SSD assembly 200 includes heat spreader 220. Heat spreader 220 may be implemented in any appropriate manner, such as by a composite material (e.g., silicone) with embedded metal to allow heat to travel from the memory modules (e.g., 107a and 107b) to the motherboard 214. In this instance, the SSD 107 acts as a heat generator, and the motherboard 214 acts as a heatsink. In some embodiments, the motherboard 214 itself may be coupled to one or more other heatsinks (not shown) to provide for further thermal dissipation.

Each of the memory modules of SSD 107 may generate heat as they perform read and write operations. The heat spreader 220 may be configured to receive that heat and to dissipate that heat through the volume and the surface area of heat spreader 220. In this example, the heat spreader 220 is in thermal contact with the memory modules (e.g., 107a and 107b) and the PCB 216 and is also in thermal contact with the motherboard 214, thereby allowing for heat dissipation from the SSD 107 to the motherboard 214. The heat spreader 220 may be configured so that it is expected, during normal operation, to provide an adequate amount of heat transfer from the SSD 107 to the motherboard 214 to avoid any throttling by the thermal algorithm 120. However, should the heat spreader 220 be absent or be ineffective, then there may not be enough heat dissipation from the SSD 107 to avoid throttling by the thermal algorithm 120.

Further in this example, the SSD assembly 200 includes two thermal sensors 210, 212. Other embodiments may include more thermal sensors, though the particular example described herein includes thermal sensors 210, 212. Thermal sensor 210 is implemented within the SSD 107. For example, thermal sensor 210 may be implemented on PCB 216 or may be implemented within one of the memory modules (e.g., 107a or 107b). Thus, thermal sensor 210 may be exposed to heat generated by the SSD 107, and it may be communicatively coupled to the chipset 102 via conductive wires in PCB 216 and motherboard 214. In other words, the chipset 102, processors 101, and EC 109 may be able to receive thermal readings from thermal sensor 210.

Thermal sensor 212 is implemented on motherboard 214. Thermal sensor 212 may be communicatively coupled to the chipset 102 via conductive wires in motherboard 214 and it may be able to provide thermal readings to chipset 102, processors 101, and EC 109. During operation, for example at startup, heat sensors 210 and 212 may provide relatively low thermal readings, and those thermal readings may be relatively close to each other. However, as time goes on, heat is generated by SSD 107, and the effects of the heat are detected at thermal sensor 210 first, so that the thermal reading of the heat sensor 210 may increase faster than the thermal readings of the heat sensor 212. As time goes on, the SSD assembly 200 may reach a thermal steady state, where the heat generated by the SSD 107 may be dissipated through the heat spreader 220 and may be detected at the thermal sensor 212. That steady state may include increases and decreases in a number of input output operations per second of the SSD 107, so that heat generation may go up and down, and a difference between the temperature readings at the thermal sensor 210 and the thermal sensor 212 may vary somewhat but may stay within a range that was designed for the heat spreader 220.

Assuming that the heat spreader 220 is installed properly and operates properly, the difference may vary but may stay within a desired range. However, if the heat spreader 220 is not installed properly or is otherwise not effectively operable, the temperature reading at thermal sensor 210 may increase at a rate greater than the rate seen at the temperature reading at thermal sensor 212. Assuming continued operation, the temperature reading at thermal sensor 210 may eventually reach a level that causes throttling by the thermal algorithm 120.

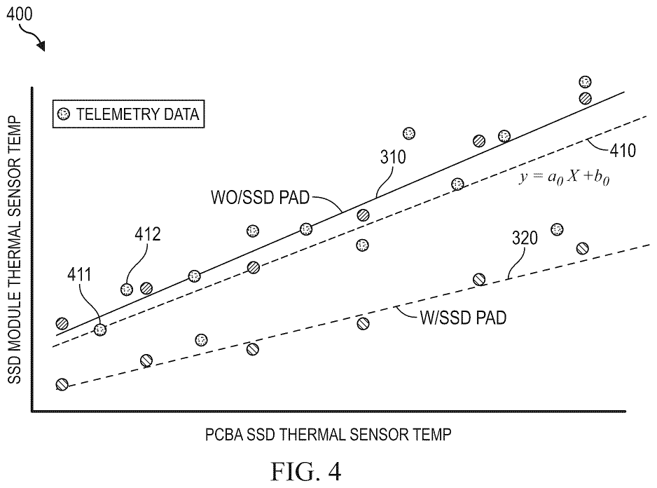

Thermal evaluation module 121 may be configured to receive the thermal readings from thermal sensors 210, 212 and to perform actions, such as described below with respect to FIGS. 4-8.

FIG. 3 is an illustration of a graph 300 of example curves 310, 320 of thermal operation of an IHS according to various embodiments. FIG. 3 illustrates functions that may be generated and analyzed before deployment of the IHS 100. For instance, a manufacturer of IHS 100 or other entity may generate the functions during manufacture or other appropriate time and may do so through testing, simulation, or other appropriate technique.

Graph 300 uses a thermal reading of thermal sensor 210 on its y-axis (a first dimension) and uses a thermal reading of thermal sensor 212 on its X axis (a second dimension). Data point 311 is plotted on graph 330 based on observed thermal readings, and the same is true for data point 312. The data points 311, 312 represent readings that would be associated with operating SSD 107 without thermal pad 220 in place. Data points 311, 312 are numbered for ease of illustration, and FIG. 3 shows additional similar data points that are associated with operation of SSD 107 without thermal pad 220.

Similarly, the data points 321, 322 represent readings that would be associated with operating SSD 107 with thermal pad 220 in place, such as illustrated in FIG. 2. Once again, data points 321, 322 are numbered for ease of illustration, and FIG. 3 shows additional similar data points that are associated with operation of SSD 107 with thermal pad 220.

The testing and/or simulation may generate more or fewer data points, each data point being associated with either operation with the thermal pad 220 or without the thermal pad 220. An IHS (IHS 100 or another IHS) may receive those data points and then perform a first curve fitting to generate curve 310 and perform a second curve fitting to generate curve 320. For instance, curve 310 is a linear curve (a line), and it may be generated by applying a linear curve fitting algorithm to the data points 311, 312, and the like. Curve 320 is also a linear curve, and it may be generated by applying a linear curve fitting algorithm to the data points 321, 322, and the like.

Linear curve fitting may be performed using any appropriate technique. Examples of techniques that may be used include least-squares linear regression, total least-squares (such as orthogonal regression), robust regression (such as M-estimators), gradient descent for linear regression, and the like.

The result of the curve fitting associated with curve 310 may generate a function y=a1x+b1, where a1 is a slope and b1 is a constant. Similarly, the result of the curve fitting associated with curve 320 may generate a function y=a1′x+b1′, where a1′ is a slope and b1′ is a constant.

In some embodiments, the functions, or at least the slopes associated with the functions, may be stored with the thermal evaluation module 121 for comparison with thermal performance observed during normal use when IHS 100 is deployed. Additionally or alternatively, an engineer may observe slopes of the functions and determine a threshold slope at which an observed performance of IHS 100 above the threshold may be more indicative of operation without heat spreader 220 and in which observed performance of IHS 100 below the threshold may be more indicative of operation with heat spreader 220. Such threshold slope (or multiple threshold slopes) may be stored with thermal evaluation module 121, as described in more detail below.

For instance, in one example, the slope (a1) associated with the curve 310 may be 3.63, and the slope (a1′) associated with the curve 320 may be 1.48. Furthermore, an engineer (or AI model or other entity) may observe the slopes of the curves 310, 320 and may determine that a threshold slope may be set at 2.1. In other words, if thermal evaluation module 121 determines that IHS 100 operates above that slope of 2.1, then thermal evaluation module 121 may determine that the heat spreader 220 may be absent. On the other hand, if thermal evaluation module 121 determines that IHS 100 operates below the threshold slope of 2.1, then thermal evaluation module 121 may determine that heat spreader 220 may be present.

FIG. 4 is an illustration of a graph 400 of example curves 310, 320, and 410, according to various embodiments. Curve 410 may be generated from the data points 411, 412 by thermal evaluation module 121. For instance, thermal sensors 210 and 212 may produce thermal readings, which may be received by thermal evaluation module 121, and thermal evaluation module 121 may generate a multitude of data points, such as illustrated by data points 411, 412. Over time (e.g., every 15 minutes or so) the thermal evaluation module 121 may generate a subsequent data point, resulting in multiple data points during operation of IHS 100. Thermal evaluation module 121 may then perform linear curve fitting to generate the function y=a0+b0, where a0 is a slope value and b0 is a constant. Curve 410 is a representation of the function y=a0+b0.

Thermal evaluation module 121 may compare the slope value a0 against a reference slope value, such as a threshold slope value, as described above. For instance, in the example above, a threshold slope value may be set at 2.1. Continuing with the example, if a0 is greater than or equal to 2.1, then thermal evaluation module 121 may determine that it is more likely that heat spreader 220 is absent, whereas if a 0 is smaller than 2.1, then thermal evaluation module 121 may determine that it is more likely that heat spreader 220 is present.

Of course, the scope of implementations is not limited to any particular slope numbers, slope thresholds, quantity of data points, or the like. Rather, the particular numbers discussed above are for example only, and a particular implementation may be adapted for use as appropriate.

In response to the analysis, the thermal evaluation module 121 may perform some action, such as alerting a user or technician if it is determined that heat spreader 220 is absent. The user or technician may then proceed as appropriate, such as scheduling a repair, performing the repair, and/or the like.

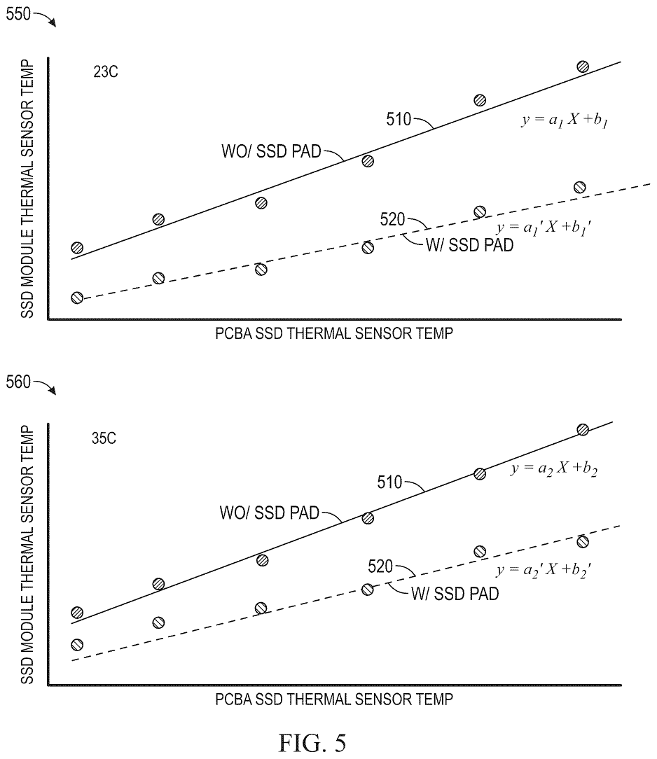

Additionally, in some implementations, the curves 310 and 320 may be different depending upon ambient temperature. FIG. 5 is an illustration of graphs 550 and 560, according to various embodiments. Curve 510 may be generated similarly to curve 310, and curve 520 may be generated similarly to curve 320, though at an ambient temperature of 23° C. in graph 550. Graph 560 illustrates curves 510 and 520 at an ambient temperature of 35° C. It is noted that the slopes of the curves 510 and 520 may be different at the different ambient temperatures. Some embodiments may include the pre-deployment activities employing testing and/or simulation at a multitude of different ambient temperatures, thereby generating curves for the different ambient temperatures, where the different curves may have different slopes depending on the corresponding ambient temperature. Furthermore, different reference slopes, such as different threshold slopes, may be established for each respective ambient temperature.

Thus, in the example above with the threshold slope being a slope value of 2.1, that threshold slope value may be different at different ambient temperatures. The thermal evaluation module 121 may store a multitude of different threshold slopes corresponding to different ambient temperatures, each with an identifier of its corresponding ambient temperature. During deployment and operation, the thermal evaluation module 121 may select an appropriate one of the threshold slopes by doing a best match with the observed ambient temperature. The thermal evaluation module 121 may then compare the observed operation of IHS 100 (e.g., slope value a0) with the reference slope value that was selected based on the observed ambient temperature.

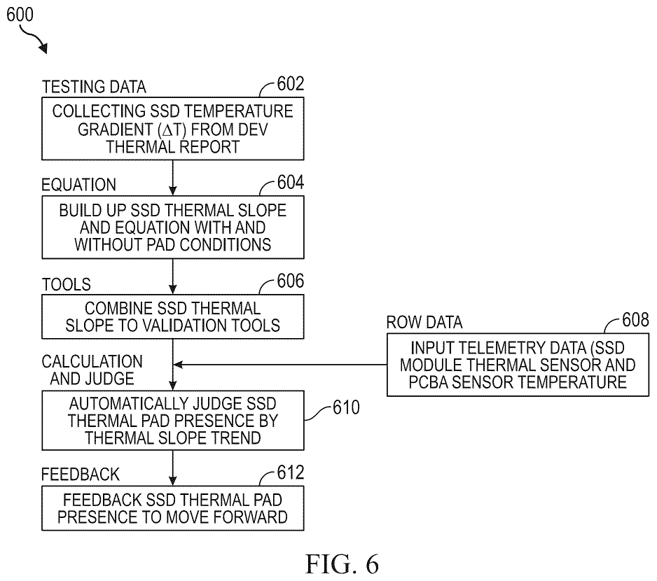

FIG. 6 is an illustration of an example method for addressing thermal performance of an IHS, according to various embodiments.

Action 602 includes a testing or simulation phase. At action 602, a manufacturer or other entity may collect temperature information from a thermal report, such as by testing or simulation. An example is discussed above at FIG. 3 and FIG. 5, where data points representing both operation with thermal pad 220 and operation without thermal pad 220 are generated. The testing and/or simulation of action 602 may be performed with respect to multiple different ambient temperatures, where an ambient temperature may include an air temperature outside of an enclosure of the IHS 100 or an approximation thereof.

At action 604, the manufacturer or other entity may then perform curve fitting operations to calculate slope values. For instance, a first slope value may be associated with operation with thermal pad 220 at a first ambient temperature, and a second slope may be associated with operation without thermal pad at the same ambient temperature. The curve fitting may be performed for each of the different ambient temperatures. Furthermore, an engineer or other entity may then assign threshold slope values based on the observations at actions 602 and 604. In one example, there may be a unique threshold slope value for each ambient temperature. Each threshold slope value may represent a value at which it is more likely that an observed thermal operation of IHS 100 is without a heat spreader if a slope value of the observed thermal operation is above the threshold slope.

At action 606, the manufacturer or other entity may store the different threshold slope values to IHS. For instance, the threshold slope values may be stored as part of the firmware of the BIOS, may be stored to system memory 103, or may be stored to some other appropriate memory accessible by IHS 100.

Following action 606, the IHS 100 may be subject to normal operation at a deployed site. During operation, IHS 100 may execute computer readable instructions to perform the functions of thermal evaluation module 121. Thermal evaluation module 121 may access thermal information, perhaps by receiving the thermal information from thermal sensors, such as thermal sensors 210, 212 of FIG. 2, at action 608.

Although the examples above refer to telemetry data from thermal sensors only, the scope of implementations may include receiving and analyzing telemetry data from other sources as well. For instance, relevant telemetry data may include power consumption, clock speed, input output operations per second of a heat generator (e.g., SSD, processor core), corrective action by thermal algorithm 120, and/or the like.

At action 610, the thermal evaluation module 121 may receive the input telemetry data observed from operation of IHS 100, may perform curve fitting, and generate a slope value based on the observed operation (an observed slope value). An example is described above with respect to curve 410 of FIG. 4.

Action 610 may further include judging whether the thermal spreader is present based on the slope value of the observed operation. For instance, the thermal evaluation module 121 may measure the current ambient temperature, may select a respective one of the stored threshold slope values based on the current ambient temperature, and may compare the selected one of the threshold slope values with the observed slope value. In one example, the thermal evaluation module 121 may determine that the heat spreader may be absent if the comparison of the observed slope value and the threshold slope value indicates that the observed slope value is greater than or equal to the threshold slope value. Similarly, the thermal evaluation module 121 may determine that the heat spreader may be present if the comparison indicates that the observed slope value is lower than the threshold slope value.

As noted above, there may be other telemetry data that is received at action 608. In some embodiments, other telemetry data may be used to inform the determination at action 610. For instance, if measured power consumption or measured input output operations per second are above one or more thresholds, then the threshold slope value may be reduced downward, thereby increasing the likelihood that the determination at action 610 indicates absence of the heat spreader. In another example, if corrective action by thermal algorithm 120 has occurred within a particular window of time, then the threshold slope value may be reduced downward, increasing the likelihood that the determination of action 610 indicates absence of the heat spreader. Of course, those are examples, and the scope of implementations may include employing the telemetry data in any appropriate manner to judge absence or presence of the heat spreader.

Action 612 is based on the determination from action 610. Specifically, action 612 may include feeding back the determination made at action 610 and then performing an appropriate response. An appropriate response may include, in the case of determining that the heat spreader is absent, scheduling a repair or replacement of the heat spreader, performing a repair or replacement of the heat spreader, alerting the user, alerting a technician, and/or the like.

Also, various embodiments may include different or fewer actions being performed by thermal evaluation module 121. For instance, in some examples, thermal evaluation module 121 may gather the telemetry data from action 608 and then transmit that telemetry data to a different IHS, such as an IHS in the cloud (not shown). The other IHS may then perform actions 610 and 612.

The principles discussed above are not limited to determining thermal performance of an SSD, as the scope of implementations may include determining thermal performance of any heat generator in an IHS, such as IHS 100. FIG. 7 illustrates an example arrangement of layers 700 in an IHS, according to some embodiments. FIG. 8 illustrates curves associated with operation of the arrangement of layers 700, according to some embodiments.

The arrangement of layers 700 includes processors 101, implemented on one or more semiconductor dies and in one or more semiconductor packages. An example physical form of processors 101 (including semiconductor packages) is shown as being disposed between PCB 714 and heat spreader 704. In other words, processors 101 are thermally coupled to PCB 714 and to heat spreader 704. Heat spreader 704 may be implemented in any appropriate manner, such as including a composite material of silicon and metal, one or more metal plates, a single metal plate, and/or the like. Heat spreader 704 may be the same as or similar to heat spreader 220, as discussed above. More specifically, heat spreader 704 is configured to receive heat generated from processors 101, dissipate that heat through the volume of heat spreader 704, and transmit that heat to heatsink 703 via the surface area of heat spreader 704. Heatsink 703 may be implemented in any appropriate manner, such as being made of a metallic material or other material and having fins or other surface area-enhancing designs. Fan 702 is thermally coupled to the heatsink 703 and is configured to dissipate heat to ambient air via airflow generated by fan 702.

Thus, processors 101 act as a heat generator, and PCB 714 and heatsink 703 act as heatsinks. PCB 714 is shown as a bottom layer in arrangement 700, processors 101 are configured as one or more layers above PCB 714, heat spreader 704 is implemented as a layer above processors 101, and heatsink 703 and fan 702 are implemented as layers above the heat spreader 704. Of course, the scope of implementations may include more or fewer layers, different types of heatsinks, may omit a fan or include more fans, as appropriate.

In arrangement 700, a first thermal sensor 710 is implemented in the heat generator (processors 101), which is analogous to how thermal sensor 210 is implemented in the heat generator of FIG. 2. Second thermal sensor 712 is implemented in the heat spreader 704. Various embodiments may include additional or alternative arrangements of thermal sensors.

As processors 101 generate heat, that heat may be detected by thermal sensor 710 and transmitted to processor 101, chipset 102, and/or EC 109. Similarly, thermal sensor 712 may also detect the heat, though that heat may be attenuated by virtue of the characteristics of heat spreader 704. Thermal sensor 712 may also be in electrical communication with processor 101, chipset 102 and/or EC 109. In any event, thermal evaluation module 121 may receive temperature measurements from thermal sensor 710, 712.

Curve 820 of FIG. 8 may be generated by performing a curve fitting on multiple data points that represent operation of the arrangement 700 with an inoperable heat spreader 704. Curve 830 may be generated by performing a curve fitting on multiple data points that represent operation of the arrangement 700 with an operable heat spreader 704. Curves 820 and 830 may be generated by testing and/or simulation and are analogous to curves 310, 320 of FIGS. 3 and 510, 520 of FIG. 5. The manufacturer or other entity may generate multiple curves 820, 830, each for a different ambient temperature, such as described above with respect to FIG. 5. Furthermore, the manufacturer or other entity may then determine reference slope values (e.g., threshold slope values) based on the curves 820, 830 and may store those values to the code for the thermal evaluation module 121.

In this example, a particular one of the threshold slopes may be configured so that observed operation of the arrangement 700 with an observed slope greater than the threshold slope may indicate inoperability of the heat spreader 704, whereas an observed slope less than the threshold slope may indicate operability of the heat spreader 704.

Thus, the actions 602-606 of FIG. 6 may be applied to the arrangement 700 to generate data points, slope values, and threshold slope values.

Curve 810 is an illustration of a function having a slope value a0 that is based on observed data points. For instance, the Y axis of graph 800 corresponds to thermal measurements of thermal sensor 712, and the X axis corresponds to thermal measurements of the thermal sensor 710. Each data point associated with curve 810 represents an X value and a Y value gathered from the thermal sensor output of sensors 710, 712, respectively. The thermal evaluation module 121 may then perform curve fitting to calculate the observed slope value a0. The thermal evaluation module 121 may then select an appropriate one of the threshold slope values based on an ambient temperature and may then compare the selected threshold slope value to the observed slope value a0. In other words, the thermal evaluation module 121 may perform action 610 on the observed slope value a0 of the arrangement 700.

The action 610 may include the thermal evaluation module 121 determining that heat spreader 704 is either operable or inoperable. The thermal evaluation module 121 may then perform a further action, such as described above at action 612. For instance, other actions may include alerting a user technician, scheduling a repair or replacement of the heat spreader 704, repairing or replacing the heat spreader 704, or other appropriate action.

To implement various operations described herein, computer program code (i.e., instructions for carrying out these operations) may be written in any combination of one or more programming languages, including an object-oriented programming language such as Java, Smalltalk, Python, C++, or the like, conventional procedural programming languages, such as the “C” programming language or similar programming languages, or any of machine learning software. These program instructions may also be stored in a computer readable storage medium that can direct a computer system, other programmable data processing apparatus, controller, or other device to operate in a particular manner, such that the instructions stored in the computer readable medium produce an article of manufacture including instructions which implement the operations specified in the block diagram block or blocks. The program instructions may also be loaded onto a computer, other programmable data processing apparatus, controller, or other device to cause a series of operations to be performed on the computer, or other programmable apparatus or devices, to produce a computer implemented process such that the instructions upon execution provide processes for implementing the operations specified in the block diagram block or blocks.

Reference is made herein to “configuring” a device or a device “configured to” perform some operation(s). It should be understood that this may include selecting predefined logic blocks and logically associating them. It may also include programming computer software-based logic of a retrofit control device, wiring discrete hardware components, or a combination thereof. Such configured devices are physically designed to perform the specified operation(s).

Modules implemented in software for execution by various types of processors may, for instance, include one or more physical or logical blocks of computer instructions, which may, for instance, be organized as an object or procedure. Nevertheless, the executables of an identified module need not be physically located together but may include disparate instructions stored in different locations which, when joined logically together, include the module and achieve the stated purpose for the module. Indeed, a module of executable code may be a single instruction, or many instructions, and may even be distributed over several different code segments, among different programs, and across several memory devices. Similarly, operational data may be identified and illustrated herein within modules and may be embodied in any suitable form and organized within any suitable type of data structure. The operational data may be collected as a single data set or may be distributed over different locations including over different storage devices.

In many implementations, systems and methods described herein may be incorporated into a wide range of electronic devices including, for example, computer systems or Information Technology (IT) products such as servers, desktops, laptops, memories, switches, routers, etc.; telecommunications hardware; consumer devices or appliances such as mobile phones, tablets, wearable devices, IoT devices, television sets, cameras, sound systems, etc.; scientific instrumentation; industrial robotics; medical or laboratory electronics such as imaging, diagnostic, or therapeutic equipment, etc.; transportation vehicles such as automobiles, buses, trucks, trains, watercraft, aircraft, etc.; military equipment, etc. More generally, these systems and methods may be incorporated into any device or system having one or more electronic parts or components.

Although the invention(s) is/are described herein with reference to specific embodiments, various modifications and changes can be made without departing from the scope of the present invention(s), as set forth in the claims below. Accordingly, the specification and figures are to be regarded in an illustrative rather than a restrictive sense, and all such modifications are intended to be included within the scope of the present invention(s). Any benefits, advantages, or solutions to problems that are described herein with regard to specific embodiments are not intended to be construed as a critical, required, or essential feature or element of any or all the claims.

Unless stated otherwise, terms such as “first” and “second” are used to arbitrarily distinguish between the elements such terms describe. Thus, these terms are not necessarily intended to indicate temporal or other prioritization of such elements. The terms “coupled” or “operably coupled” are defined as connected, although not necessarily directly, and not necessarily mechanically. The terms “a” and “an” are defined as one or more unless stated otherwise. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

1. An Information Handling System (IHS), comprising:
a processor; and
a memory coupled to the processor, the memory having program instructions stored thereon that, upon execution by the processor, cause the IHS to:
access first temperature information for a first thermal sensor disposed on a first layer in an information handling system (IHS);
access second temperature information for a second thermal sensor disposed on a second layer in the IHS;
generate a plurality of data points over time, wherein each of the data points represents a first dimension associated with the first temperature information and a second dimension associated with the second temperature information;
determine a linear function based on the plurality of data points; and
evaluate a presence of a heat spreader between the first thermal sensor and the second thermal sensor or an effectiveness of the heat spreader based on the linear function.

2. The IHS of claim 1, wherein the IHS comprises a heat source in the first layer, and wherein the second layer comprises the heat spreader.

3. The IHS of claim 2, wherein the heat source comprises a processor core.

4. The IHS of claim 2, wherein the program instructions to cause the IHS to evaluate the effectiveness of the heat spreader includes program instructions to cause the IHS to:
determine a slope of the linear function;
compare the slope of the linear function to a reference slope; and
determine whether the heat spreader is operable based on comparing the slope of the linear function to the reference slope.

5. The IHS of claim 4, further comprising program instructions to cause the IHS to:
select the reference slope from a plurality of reference slopes based on an ambient temperature of the IHS and an ambient temperature correspondence of the reference slope.

6. The IHS of claim 1, wherein the program instructions to cause the IHS to evaluate the presence of the heat spreader includes program instructions to cause the IHS to:
determine a slope of the linear function;
compare the slope of the linear function to a reference slope; and
determine that the heat spreader is either present or not present based on comparing the slope of the linear function to the reference slope.

7. A hardware memory device having program instructions stored thereon that, upon execution by a processor of an Information Handling System (IHS), cause the IHS to:
receive first telemetry data and second telemetry data from a first sensor and a second sensor, respectively, of the IHS;
generate a plurality of data points over time, wherein each of the data points represents the first telemetry data and the second telemetry data;
determine a linear function based on the plurality of data points;
evaluate a slope of the linear function; and
determine that a heat spreader is either not present in the IHS or is not operable in the IHS based on evaluating the slope of the linear function.

8. The hardware memory device of claim 7, further comprising program instructions to cause the IHS to:
select a reference slope from a plurality of reference slopes based on an ambient temperature of the IHS; and
compare the reference slope to the slope of the linear function, wherein the program instructions to cause the IHS to determine that the heat spreader is not present in the IHS includes program instructions to cause the IHS to determine that the slope of the linear function is greater than the reference slope.

9. The hardware memory device of claim 7, further comprising program instructions to cause the IHS to:
select a reference slope from a plurality of reference slopes based on an ambient temperature of the IHS; and
compare the reference slope to the slope of the linear function, wherein the program instructions to cause the IHS to determine that the heat spreader is not operable in the IHS includes program instructions to cause the IHS to determine that the slope of the linear function is greater than the reference slope.

10. The hardware memory device of claim 7, wherein the program instructions are included within a basic input output system (BIOS) of the IHS.

11. The hardware memory device of claim 7, wherein the first telemetry data comprises temperature data from a first thermal sensor disposed on a circuit board, and wherein the second telemetry data comprises temperature data from a second thermal sensor disposed within a heat generator of the IHS.

12. The hardware memory device of claim 7, wherein the first telemetry data comprises temperature data from a first thermal sensor disposed in the heat spreader, and wherein the second telemetry data comprises temperature data from a second thermal sensor disposed within a heat generator of the IHS.

13. A method comprising:
accessing first temperature information for a first thermal sensor disposed on a storage drive of an information handling system (IHS);
accessing second temperature information for a second thermal sensor disposed on a circuit board, wherein the storage drive is arranged above the circuit board;
generating a plurality of data points over time, wherein each of the data points represents a first dimension associated with the first temperature information and a second dimension associated with the second temperature information;
determining a linear function based on the plurality of data points; and
determining whether a heat spreader is disposed between the first thermal sensor and the second thermal sensor based on the linear function.

14. The method of claim 13, wherein determining whether the heat spreader is disposed between the first thermal sensor in the second thermal sensor comprises:
determining a slope of the linear function;
comparing the slope of the linear function to a reference slope; and
determining that the heat spreader is disposed between the first thermal sensor and the second thermal sensor based on comparing the slope of the linear function to the reference slope.

15. The method of claim 14, wherein determining that the heat spreader is disposed is based on determining that the slope of the linear function is less than the reference slope.

16. The method of claim 13, wherein determining whether the heat spreader is disposed between the first thermal sensor and the second thermal sensor comprises:
determining a slope of the linear function;
comparing the slope of the linear function to a reference slope; and
determining that the heat spreader is not disposed between the first thermal sensor in the second thermal sensor based on comparing the slope of the linear function to the reference slope.

17. The method of claim 16, wherein determining that the heat spreader is not disposed is based on determining that the slope of the linear function is greater than the reference slope.

18. The method of claim 13, further comprising:
maintaining a plurality of reference slopes, each reference slope of the plurality of reference slopes being associated with a respective ambient temperature.

19. The method of claim 18, wherein determining whether the heat spreader is disposed between the first thermal sensor in the second thermal sensor comprises:
determining a slope of the linear function;
selecting a reference slope of the plurality of reference slopes based on an ambient temperature of the IHS; and
comparing the slope of the linear function to the first reference slope.

20. The method of claim 13, further comprising:
installing the heat spreader between the first thermal sensor and the second thermal sensor in response to determining that the heat spreader is not disposed between the first thermal sensor and the second thermal sensor.
